(19) United States
(12) Patent Application Publication
(10) Pub. No.: US 2026/0206278 A1
(43) Pub. Date: Jul. 16, 2026

(54) SEMICONDUCTOR DEVICE WITH FRONT VIA

(71) Applicant: INTERNATIONAL BUSINESS MACHINES CORPORATION, ARMONK, NY (US)

(72) Inventors: Anindya Nath, Watervliet, NY (US); Robert Gauthier, Williston, VT (US); Masoud Zabihi, Schenectady, NY (US); Anthony I-Chih Chou, Guilderland, NY (US)

(21) Appl. No.: 19/023,149

(22) Filed: Jan. 15, 2025

(51) Int. Cl. H10D 64/23; H10D 84/01; H10D 84/83

(52) U.S. Cl. CPC H10D 64/254; H10D 84/013; H10D 84/0149; H10D 84/832; H10D 84/835

(57) ABSTRACT

A semiconductor device includes a first well region, a second well region adjacent to the first well region, a plurality of doped regions over the first well region and the second well region, a first backside via on a first end of the semiconductor device, a second backside via on a second end of the semiconductor device, a first deep via connecting the first backside via to a frontside contact, a second deep via over the second backside via, and shallow trench isolation (STI) covering the first deep via and the second deep via. The first backside via and the second backside via are covered by a spacer liner.

### BACKGROUND

### Technical Field

The present disclosure generally relates to semiconductors, and more particularly, to semiconductors with front via structure, and methods of creation thereof.

### Description of Related Art

The continuous miniaturization of transistors and their increasing density on chips are hallmark innovations in the semiconductor industry, closely following Moore’s Law. This trend has enabled transistors to shrink to nanometer scales, allowing millions, and even billions, to be integrated onto a single chip. This advancement significantly boosts computational power and energy efficiency. The evolution towards system-on-chip architectures further enhances these capabilities by integrating various functionalities, such as processing and sensing, into a single chip.

### SUMMARY

According to an embodiment, a semiconductor device includes a first well region, a second well region adjacent to the first well region, a plurality of doped regions over the first well region and the second well region, a first backside via on a first end of the semiconductor device, a second backside via on a second end of the semiconductor device, a first deep via connecting the first backside via to a frontside contact, a second deep via over the second backside via, and shallow trench isolation (STI) covering the first deep via and the second deep via. The first backside via and the second backside via are covered by a spacer liner.

In one embodiment, the semiconductor device includes a plurality of source/drain regions. Each of the plurality of source/drain regions are bounded by a gate region.

In one embodiment, the semiconductor device includes a portion of the STI within the second well region beneath a source region and a drain region.

In one embodiment, each of the gate regions extends over the first well and the second well junction, and each of the gate regions has no doped region adjacent to it in a drain side.

In one embodiment, the semiconductor device is isolated laterally by a through-via interconnect.

In one embodiment, the semiconductor device is isolated vertically by a low-k interlayer dielectric (ILD).

In one embodiment, the semiconductor device includes horizontally oriented nanosheet gates. The horizontally oriented nanosheet gates include silicon.

In one embodiment, the semiconductor device includes a gate contact over at least one of the gate regions.

According to an embodiment, a method for fabrication of a semiconductor device includes forming a first well region, forming a second well region adjacent to the first well region, forming a plurality of doped regions over the first well region and the second well region, forming a first backside via on a first end of the semiconductor device, forming a second backside via on a second end of the semiconductor device, forming a first deep via connecting the first backside via to a frontside contact, forming a second deep via over the second backside vi, covering the first deep via and the second deep via shallow trench isolation (STI), and covering the first backside via and the second backside via by a spacer liner.

In one embodiment, the method includes forming a plurality of source/drain regions, and bounding each of the plurality of source/drain regions by a gate region.

In one embodiment, the method includes forming a portion of the STI within the second well region beneath a source region and a drain region.

In one embodiment, the method includes extending each of the gate regions over the first well and the second well junction. Each of the gate regions has no doped region adjacent to it in a drain side.

In one embodiment, the method includes laterally isolating the semiconductor device by a through-via interconnect.

In one embodiment, the method includes vertically isolating the semiconductor device by a low-k interlayer dielectric (ILD).

In one embodiment, the method includes forming horizontally oriented nanosheet gates, wherein the horizontally oriented nanosheet gates include silicon.

In one embodiment, the method includes forming a gate contact over at least one of the gate regions.

According to an embodiment, a semiconductor device includes a well region, a plurality of doped regions over the well region, a backside via on a first end of the semiconductor device, a deep via connecting the backside via to a frontside contact, shallow trench isolation (STI) covering the deep via. Each of the gate regions extends over the first well and the second well junction, and each of the gate regions has no doped region adjacent to it in a drain side.

In one embodiment, the backside via is covered by a spacer liner.

In one embodiment, the semiconductor device includes a plurality of source/drain regions. Each of the plurality of source/drain regions are bounded by a gate region.

In one embodiment, the semiconductor device includes horizontally oriented nanosheet gates, wherein the horizontally oriented nanosheet gates include silicon, and a gate contact over at least one of the gate regions.

These and other features will become apparent from the following detailed description of illustrative embodiments thereof, which is to be read in connection with the accompanying drawings.

### BRIEF DESCRIPTION OF THE DRAWINGS

The drawings are of illustrative embodiments. They do not illustrate all embodiments. Other embodiments may be used in addition or instead. Details that may be apparent or unnecessary may be omitted to save space or for more effective illustration. Some embodiments may be practiced with additional components or steps and/or without all the components or steps that are illustrated. When the same numeral appears in different drawings, it refers to the same or like components or steps.

FIGS. 1A-1C illustrate a semiconductor device, according to an embodiment.

FIGS. 2A-2B illustrate a semiconductor device after the front end of line processes, in accordance with some embodiments.

FIGS. 3A-3B illustrate a semiconductor device after the middle of line and back end of line processes, in accordance with some embodiments.

FIGS. 4A-4B illustrate a semiconductor device after the substrate removal, in accordance with some embodiments.

FIGS. 5A-5B illustrate a semiconductor device after the removal of the etch stop layer, in accordance with some embodiments.

FIGS. 6A-6B illustrate a semiconductor device after the forming the backside interlayer dielectric, in accordance with some embodiments.

FIGS. 7A-7B illustrate a semiconductor device after the patterning of the backside metal layer, in accordance with some embodiments.

FIGS. 8A-8B illustrate a semiconductor device after the formation spacer, in accordance with some embodiments.

FIG. 9 illustrates a block diagram of a method for forming the semiconductor device, in accordance with an embodiment.

### DETAILED DESCRIPTION

### Overview

In the following detailed description, numerous specific details are set forth by way of examples to provide a thorough understanding of the relevant teachings. However, it should be apparent that the present teachings may be practiced without such details. In other instances, well-known methods, procedures, components, and/or circuitry have been described at a relatively high-level, without detail, to avoid unnecessarily obscuring aspects of the present teachings.

In one aspect, spatially related terminology such as “front,” “back,” “top,” “bottom,” “beneath,” “below,” “lower,” above,” “upper,” “side,” “left,” “right,” and the like, is used with reference to the orientation of the Figures being described. Since components of embodiments of the disclosure can be positioned in a number of different orientations, the directional terminology is used for purposes of illustration and is in no way limiting. Thus, it will be understood that the spatially relative terminology is intended to encompass different orientations of the device in use or operation in addition to the orientation depicted in the figures. For example, if the device in the figures is turned over, elements described as “below” or “beneath” other elements or features would then be oriented “above” the other elements or features. Thus, for example, the term “below” can encompass both an orientation that is above, as well as below. The device may be otherwise oriented (rotated 90 degrees or viewed or referenced at other orientations) and the spatially relative descriptors used herein should be interpreted accordingly.

As used herein, the terms “lateral” and “horizontal” describe an orientation parallel to a first surface of a chip.

As used herein, the term “vertical” describes an orientation that is arranged perpendicular to the first surface of a chip, chip carrier, or semiconductor body.

As used herein, the terms “coupled” and/or “electrically coupled” are not meant to mean that the elements must be directly coupled together—intervening elements may be provided between the “coupled” or “electrically coupled” elements. In contrast, if an element is referred to as being “directly connected” or “directly coupled” to another element, there are no intervening elements present. The term “electrically connected” refers to a low-ohmic electric connection between the elements electrically connected together.

Although the terms first, second, etc., may be used herein to describe various elements, these elements should not be limited by these terms. These terms are only used to distinguish one element from another. For example, a first element could be termed a second element, and, similarly, a second element could be termed a first element, without departing from the scope of example embodiments. As used herein, the term “and/or” includes any and all combinations of one or more of the associated listed items.

Example embodiments are described herein with reference to cross-sectional illustrations that are schematic illustrations of idealized or simplified embodiments (and intermediate structures). As such, variations from the shapes of the illustrations as a result, for example, of manufacturing techniques and/or tolerances, may be expected. Thus, the regions illustrated in the figures are schematic in nature and their shapes do not necessarily illustrate the actual shape of a region of a device and do not limit the scope.

It is to be understood that other embodiments may be used and structural or active changes may be made without departing from the spirit and scope defined by the claims. The description of the embodiments is not limiting. In particular, elements of the embodiments described hereinafter may be combined with elements of different embodiments.

The semiconductor industry is increasingly adopting backside interconnect technology as the preferred approach for future device development. Backside interconnects involve routing the wiring and connections on the backside of the semiconductor wafer, as opposed to the traditional method of placing them on the front side. The shift addresses several challenges associated with front-side interconnects, such as wiring congestion, signal delays, and limitations in scaling. By utilizing the backside for interconnections, designers can alleviate the density of wiring on the front, allowing for more transistors to be placed in a given area and improving overall device performance. Backside interconnects also reduce the resistance and capacitance associated with interconnects, leading to faster signal propagation and lower power consumption.

In the context of advanced semiconductor technologies such as nanosheet transistors, the integration of backside power delivery becomes even more important. Nanosheet technologies represent an evolution in transistor architecture, where the channel is formed by stacking ultra-thin sheets of semiconductor material. These gate-all-around (GAA) structures offer superior control over the channel and enable continued scaling of transistor dimensions. However, as devices shrink and the number of transistors per unit area increases, power delivery and thermal management become significant concerns.

Disclosed semiconductor device pertains to a laterally diffused metal oxide semiconductor, LDMOS devices, which are components in nanosheet technologies that incorporate backside power delivery. The disclosed LDMOS transistors can be designed to handle higher voltages and power levels, making them suitable for power management within integrated circuits. In nanosheet technologies, where the backside of the wafer is used for power delivery networks, the disclosed LDMOS devices can be employed to efficiently manage the distribution of power across the chip. Their ability to operate with high efficiency at elevated voltages complements the needs of backside power architectures.

Further, the integration of the LDMOS devices into nanosheet technologies with backside power addresses the challenges of power distribution in highly scaled devices. Backside power delivery networks reduce voltage drops and improve power integrity by providing a direct path for power to the transistors without the resistive losses associated with front-side metallization layers. The LDMOS devices, with their high breakdown voltage and robustness, can control and regulate the power delivered through these backside networks.

The disclosed semiconductor device is an LDMOS transistor implemented using nanosheet technology and featuring a front via for backside power interconnect. Such a design merges the robust performance characteristics of LDMOS transistors with the advanced scaling capabilities of nanosheet architectures, resulting in a device optimized for high-power and high-frequency applications.

In the disclosed semiconductor device, the LDMOS transistor leverages the nanosheet structure, where ultra-thin semiconductor layers are stacked horizontally to form the channel region. The nanosheet configuration provides electrostatic control over the channel by surrounding it with gate material on all sides, also known as a gate-all-around (GAA) configuration. Such a control minimizes short-channel effects and allows for continued scaling of the transistor dimensions, which is essential as the industry moves towards technology nodes like 2 nanometers.

The lateral diffusion characteristic of the LDMOS transistor means that the drain region extends laterally away from the gate, creating a drift region that can withstand higher voltages. This design can facilitate handling the elevated drain-to-source voltages typical in power management and radio frequency (RF) applications. By integrating the LDMOS structure into nanosheet technology, the semiconductor device benefits from reduced parasitic resistances and capacitances, leading to improved efficiency and faster switching speeds.

The inclusion of a front via for backside power interconnect is an advancement in power delivery methodology within the semiconductor device. The front via provides a conductive pathway from the front side of the transistor directly to the backside power delivery network. By routing power through the backside, the device alleviates congestion in the front-side metal layers, which is important as devices become more densely packed. The configuration reduces voltage drops and resistive losses associated with traditional front-side power distribution networks.

Backside power interconnects enhance the overall performance of the device by providing a more efficient and direct power supply to the active regions of the transistor. The direct connection minimizes the distance that power must travel, reducing the associated resistive losses and improving power integrity across the chip. Additionally, the backside power delivery allows for better thermal management. Heat generated in the active regions can be more effectively dissipated through the backside, improving the reliability and longevity of the device under high-power operation.

Further, the combination of LDMOS transistors with nanosheet technology and backside power interconnect addresses the challenges in modern semiconductor design, as it enables high-voltage operation within a scaled-down device footprint, meeting the demands of applications that require both power efficiency and miniaturization. The nanosheet architecture allows for tight control over the electrical characteristics of the transistor, such as threshold voltage and drive current, enabling precise tuning for specific applications.

Furthermore, the device's architecture is conducive to integration with other advanced technologies. The use of nanosheets facilitates compatibility with existing fabrication processes while paving the way for future scaling. The backside power interconnect is aligned with industry trends toward three-dimensional integration and heterogeneous integration, where different types of devices are stacked or combined within a single package.

The disclosed semiconductor device represents a convergence of cutting-edge technologies aimed at optimizing performance, efficiency, and scalability. By incorporating an LDMOS transistor within nanosheet technology and utilizing a front via for backside power interconnect, the device achieves electrical characteristics suitable for next-generation electronic systems. Such as design is poised to meet the increasing demands for high-speed, high-power, and energy-efficient components in a wide range of applications, from telecommunications infrastructure to advanced computing systems.

Accordingly, the teachings herein provide methods and systems of semiconductor devices with front via and backside power delivery network structure. The techniques described herein may be implemented in a number of ways. Example implementations are provided below with reference to the following figures.

### Example Semiconductor Device with Front Via and Backside Power Delivery Network Structure

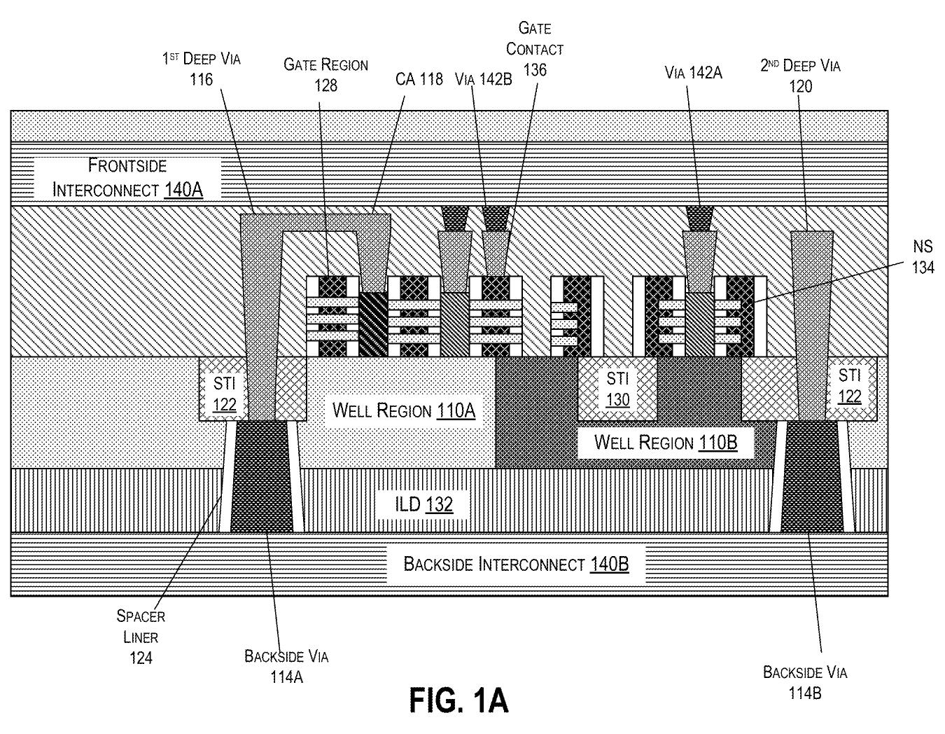

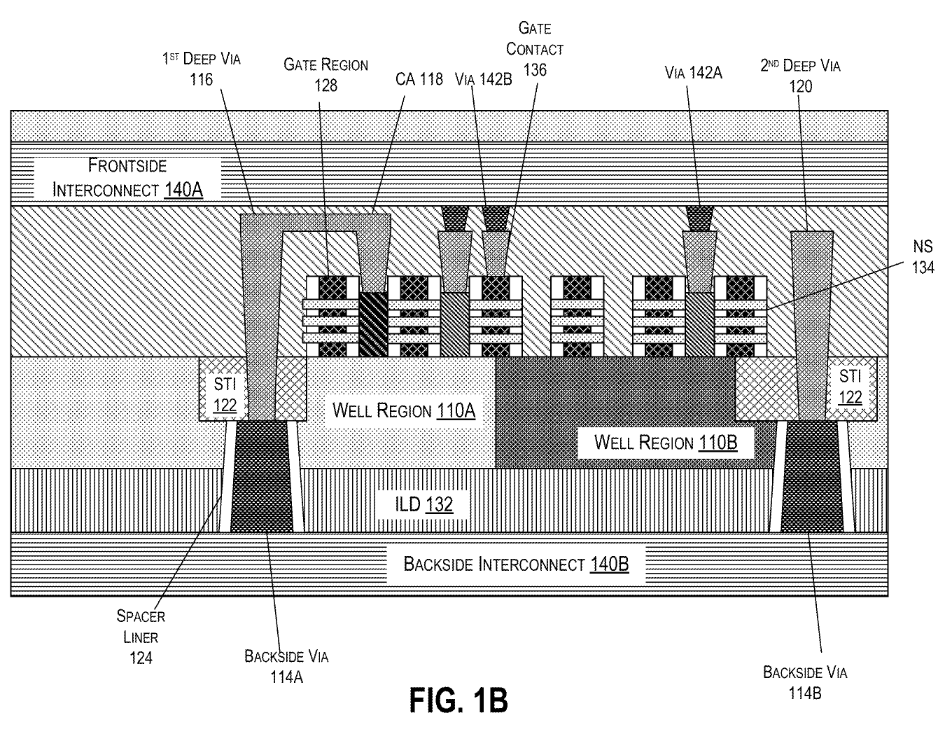

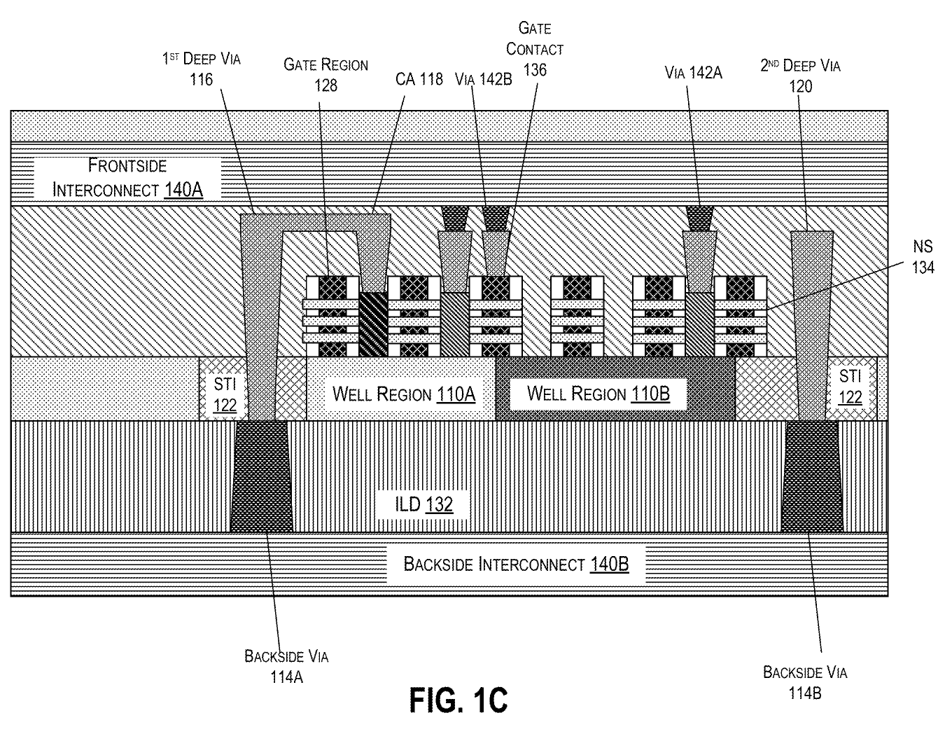

Reference now is made to FIGS. 1A-1B, which are simplified cross-section views of a of the semiconductor device. The semiconductor device includes a first well region 110A, a second well region 110B, a plurality of doped regions, aka source/drain regions, S/D, a first backside via 114A, a second backside via 114B, a first deep via 116, a frontside contact 118, a second deep via 120, shallow trench isolation, STI 122, a spacer liner 124, a gate region 128, an interlayer dielectric, ILD 132, nanosheet gates, NS 134, a gate contact 136, a frontside interconnect 140A, a backside interconnect 140B, a first frontside via 142A, and a second frontside via 142B.

In some embodiments, the semiconductor device includes a first well region 110A. The first well region 110A can serve as a foundational layer within the semiconductor substrate, and can be doped to exhibit specific electrical properties. By introducing impurities of a certain type (either n-type or p-type), the first well region 10A can control the behavior of charge carriers within the semiconductor device. The doping can facilitate forming p-n junctions and enabling the operation of various semiconductor devices such as transistors and diodes. The first well region's properties can be tailored to optimize device performance, reduce leakage currents, and enhance the overall efficiency of the semiconductor device.

In some embodiments, the semiconductor device includes a second well region 110B adjacent to the first well region 110A. The adjacency of the first well region 110A and the second well region 110B can allow for the formation of junctions necessary for device operation. The second well region 110B can be doped differently from the first well region 110A, e.g., opposite type, creating a p-n junction at their interface. The junction can control the flow of electrons and holes, enabling the semiconductor device to function effectively in applications such as amplification, switching, and signal modulation.

In some embodiments, the semiconductor includes a plurality of doped regions over the first well region 110A and the second well region 110B. The plurality of doped regions can form the active areas of semiconductor device, acting as source and drain regions. By precisely controlling the doping concentration and profiles, the plurality of doped regions can facilitate charge carrier injection and collection, which can enhance the device's electrical characteristics, such as drive current capability, switching speed, and threshold voltage control. The placement of the plurality of doped regions over the first well region 110A and the second well region 110B can enable the formation of various device architectures suitable for high-performance applications.

In some embodiments, the semiconductor includes a first backside via 114A on a first end of the semiconductor device. The first backside via 114A provides an electrical connection from the backside of the semiconductor substrate to the frontside circuitry. The first backside via 114A can enable power delivery and signal routing, reduce parasitic resistance and improve overall device performance. Utilizing the first backside via 114A can further help in minimizing the routing congestion on the front side, allowing for higher integration density and more complex circuitry within a limited area.

In some embodiments, the semiconductor includes a second backside via 114B on a second end of the semiconductor device. Similar to the first backside via 114A, the second backside via 114B can facilitate electrical connectivity between the backside and frontside of the device. Having backside vias at both ends can enhance the flexibility in circuit design and power distribution, enable symmetrical layouts and balanced signal paths. Such a configuration can particularly be beneficial in high-speed and high-frequency applications where signal integrity and timing are of essence.

In some embodiments, the semiconductor includes a first deep via 116 connecting the first backside via 114A to a frontside contact 118. The first deep via 116 can traverse the semiconductor substrate, creating a conductive pathway between the backside and the frontside contact. The first deep via 116 can allow for direct electrical connections, reduce the length of interconnects and associated parasitic effects. By connecting the first backside via 114A to the frontside contact 118, the semiconductor device can achieve efficient power delivery and improved thermal management, which is beneficial for high-performance and power-intensive applications.

The frontside contact 118, located over the S/D, can establish connections between the S/D and BEOL. The frontside contact 118 can ensure efficient electrical routing and connectivity within the semiconductor device. The fabrication of the frontside contact 118 can involve lithography and etching processes to define the contact area. The frontside contact 118 can be made using conductive materials such as copper (Cu) or tungsten (W).

In some embodiments, the semiconductor includes a second deep via 120 over the second backside via 114B. The second deep via 120 can function similarly to the first deep via 116, providing an additional conductive path for electrical connections within the semiconductor device. The presence of multiple deep vias can enhance the device's ability to handle higher current densities and facilitate distribution of power and signals, which is advantageous in applications that require robust performance and reliability under demanding operational conditions.

In some embodiments, the semiconductor includes shallow trench isolation, STI 122, covering the first deep via 116 and the second deep via 120. The STI 122 can include insulating structures formed by etching shallow trenches into the semiconductor substrate and filling them with dielectric materials such as silicon dioxide. Covering the deep vias with the STI 122 can provide electrical isolation from the surrounding semiconductor material, and prevent leakage currents and crosstalk between adjacent components. The isolation can maintain the integrity of the device's electrical characteristics and ensuring reliable operation in complex integrated circuits.

In some embodiments, the first backside via 116 and the second backside via 114B are covered by a spacer liner 124. The spacer liner 124 can be a dielectric layer that surrounds the backside vias, offering insulation and protection. The spacer liner 124 can help in preventing unwanted diffusion of dopants and protect the vias during subsequent fabrication processes such as etching and deposition. By covering the vias with the spacer liner 124, the semiconductor device can enhance its structural integrity and reduces the risk of electrical shorts, contributing to improved reliability and longevity.

In some embodiments, the semiconductor includes a plurality of source/drain regions, S/D. Each S/D can be bounded by a gate region 128. The source and drain regions are heavily doped areas that serve as the terminals for charge carriers entering and exiting the transistor channel. The gate region 128, positioned between the source and drain, controls the flow of carriers through the channel by applying an electric field. Bounding each S/D with a gate region 128 can allow for modulation of the channel conductivity, enable efficient switching and amplification in digital and analog circuits. Such a configuration is fundamental to the operation of metal-oxide-semiconductor field-effect transistors (MOSFETs) used in a wide range of electronic devices.

Generally, the source/drain regions are salient components that play relevant roles in the semiconductor device’s operation. In various embodiments, the S/D are region within the semiconductor material, e.g., the semiconductor device, where the current flows in and out of the semiconductor device.The source region is the region through which the majority of charge carriers (e.g., electrons or holes) enter the channel of the semiconductor device and is responsible for providing the current that flows through the semiconductor device. The source region is typically doped to have an excess of charge carriers, creating a region with high carrier concentration. This abundance of carriers allows for the efficient injection of electrons or holes into the channel when a voltage is applied.

The drain region, on the other hand, is the region where the majority of charge carriers exit the channel. The drain region receives the current from the channel and carries the charge away from the transistor. Similar to the source, the drain region is also doped to have a high carrier concentration. The doping profile in the drain region ensures that carriers can easily flow out of the channel and into the drain region.

In various embodiments, the gate regions 128 serve as control elements that regulate the flow of current through the semiconductor device. The gate regions 128 can be composed of a conductive material. The gate regions 128 can control the flow of electric current between the source and drain regions. In addition to acting as a switch, modulating the gate voltage can enable the gate regions 128 to control the current flowing through the channel region, resulting in amplified output signals.

In an embodiment, the gate regions 128 can enable the implementation of Boolean logic operations, such as AND, OR, and NOT, by controlling the flow of current based on the input voltages. In some embodiments, the gate regions, along with other active device components, can facilitate the miniaturization and integration of electronic circuits. The ability to control the channel region’s conductivity through the gate voltage allows for compact and highly efficient circuit designs.

In some embodiments, the semiconductor includes a portion of STI 130 within the second well region 110B beneath a source region and a drain region. Incorporating the portion of STI 130 beneath the source and drain regions provides vertical electrical isolation from the underlying substrate, which reduces parasitic capacitance and leakage currents, enhancing the transistor's performance, especially at high frequencies. The portion of STI 130 can act as a barrier to unwanted substrate coupling, which can degrade signal integrity and overall device efficiency.

In some embodiments, each of the gate regions extends over the junction between the first well region 110A and the second well region 110B. By extending the gate region 128 over the well junction, the semiconductor device can effectively control the carrier flow across the p-n junction formed by the adjacent well regions. This configuration allows for enhanced electrostatic control of the channel, improving the device's threshold voltage stability and reducing short-channel effects.

In some embodiments, the gate region 128 has no doped region adjacent to it on the drain side. The absence of a heavily doped region next to the gate on the drain side can help in reducing the electric field peaks that can occur at the drain end of the channel. Such a reduction mitigates hot-carrier effects, which are phenomena where high-energy carriers can degrade the gate oxide or the semiconductor material, leading to device reliability issues. By designing the doping profiles around the gate regions, the semiconductor device can offer improved durability and performance, especially under high-voltage or high-frequency operation.

In some embodiments, the semiconductor device is isolated laterally by a through-via interconnect. The through-via interconnect can include the backside vias and the deep vias and serve as both a conductive pathway and a lateral isolation barrier. By embedding interconnects that penetrate through the semiconductor layers, the semiconductor device can achieve high-density integration while maintaining electrical isolation between adjacent components. This lateral isolation can facilitate minimizing crosstalk and interference in densely packed circuits, which can help maintaining signal integrity and achieving high-speed operation.

In some embodiments, the semiconductor device is isolated vertically by a low-k interlayer dielectric, ILD 132. The ILD material, characterized by its low dielectric constant, is used between metal interconnect layers to reduce parasitic capacitance. Vertical isolation using the ILD 132 can enhance the device's performance by allowing faster signal propagation and reducing power consumption.

In some embodiments, the semiconductor includes horizontally oriented nanosheet gates, NS 134. The NS 134 can include silicon. The NS 134 can be ultra-thin, flat semiconductor layers that form the channel region of transistors. By orienting these nanosheets horizontally, the semiconductor device maximizes the effective channel width while maintaining excellent electrostatic control over the channel. Silicon can be used for the nanosheets due to its well-understood material properties, compatibility with existing fabrication processes, and excellent carrier mobility. The use of horizontally oriented silicon nanosheet gates enables the development of gate-all-around (GAA) transistor architectures, which offer improved scalability and performance over traditional FinFET designs.

In some embodiments, the semiconductor includes a gate contact 136 over at least one of the gate regions. The gate contact 136 provides a direct electrical connection to the gate electrode, allowing for the application of control voltages necessary to modulate the transistor's channel conductivity. Placing the gate contact 136 over the gate region 128 minimizes resistance and inductance in the gate signal path for high-speed switching and reducing signal delays.

Reference is now made to FIG. 1B, in which a semiconductor device is lustrated according to some embodiments. In some embodiments, the semiconductor device is a double-diffused metal oxide semiconductor, DEMOS, transistor. The DEMOS structure can be designed to handle high voltages and power levels. By utilizing a double diffusion process, the device forms graded doping profiles in the channel and drain regions, which enhances the breakdown voltage and reduces electric field peaks within the transistor. This design mitigates issues such as hot carrier injection and impact ionization, thereby improving the reliability and longevity of the device.

In some embodiments, the semiconductor device includes a PN junction formed on the bottom ILD, BILD. The PN junction serves as a component in isolating the device from the substrate, reducing parasitic capacitance and minimizing leakage currents. By positioning the PN junction on the BILD, the device enhances its high-frequency performance and prevents unwanted coupling between the active regions and the substrate. In some embodiments, a PN junction is located underneath the nanosheet bottom gate. Placing the PN junction beneath the nanosheet gate allows for control over the electric field distribution within the device. Such a configuration enhances the modulation of the channel conductivity, improves threshold voltage stability, and reduces short-channel effects.

In some embodiments, the semiconductor device includes a reverse-biased PN junction serving as an isolating device with a specific breakdown voltage. The reverse-biased junction acts as a barrier under normal operating conditions, preventing current flow and electrically isolating different regions within the semiconductor device. The breakdown voltage of this junction is carefully engineered to ensure it can withstand operational voltages without entering breakdown prematurely. In some embodiments, the source or drain is located only on one side of the gate. Having the source (or drain) on only one side of the gate creates an asymmetric device structure that can offer improved control over the electric field distribution and enhance the device's high-voltage performance. Such a design reduces the peak electric fields near the drain region, mitigating hot-carrier effects and improving the breakdown voltage and simplifies the fabrication process and can lead to reduced parasitic capacitances, which enhances the switching speed and overall efficiency of the device.

In such embodiments, the semiconductor device includes epitaxial junctions, S/D bounded by gate region 128. The formation of the junctions involves growing crystalline semiconductor layers on the substrate with precise doping profiles. Bounding the S/D with gate region 128 can allow for enhanced control of charge carrier injection and collection. In some embodiments, P+ and N+ epitaxial junctions are formed within the device. These heavily doped regions serve as sources and drains for charge carriers. The use of epitaxial growth techniques ensures high-quality junctions with low defect densities. The control over doping concentrations and junction depths enhances the device's ability to handle higher current densities and improves its suitability for power applications and high-speed switching circuits.

In some embodiments, first well region 110A and the second well region 110B are formed within the semiconductor substrate. By carefully controlling the doping types and concentrations in the N-well and P-well regions, the semiconductor device can form p-n junctions necessary for transistor operation. In some embodiments, the semiconductor device is a P+/P-well/N-well/N+ LDMOS transistor. The semiconductor device structure features a sequence of doped regions that create a high-voltage device capable of handling significant power levels. The P+ source region, P-well, N-well drift region, and N+ drain region form a lateral configuration that allows the device to support high drain-to-source voltages while maintaining good on-state performance.

In some embodiments, the semiconductor device has no STI between the N+ source and N+ drain epitaxial junctions. By eliminating the STI in this region, the device reduces parasitic resistance and capacitance, which enhances current flow and improves switching speeds. Such a design can also minimize the device's footprint, allowing for higher integration densities on the semiconductor chip.

In some embodiments, the gate region 128 extends over the N-well and P-well junction. Extending the gate region 128 over the well junction allows for enhanced electrostatic control of the channel region formed at the interface of the N-well and P-well, which improves threshold voltage modulation and reduces short-channel effects, which is particularly beneficial in scaled devices where maintaining control over the channel is challenging due to reduced dimensions. In some embodiments, the gate region 128 has no epitaxial region adjacent to it on the drain side. The absence of an epitaxial region next to the gate region on the drain side reduces the electric field peaks that typically occur near the drain end of the channel. This reduction mitigates hot-carrier effects, enhances the breakdown voltage, and improves the reliability and longevity of the device.

In some embodiments, the semiconductor device is isolated laterally by front via interconnects. Lateral isolation using front via interconnects provides a physical barrier between devices on the same substrate, preventing electrical crosstalk and interference between adjacent components. This isolation technique is essential for maintaining signal integrity in densely packed integrated circuits. The front vias also serve as conductive pathways for electrical connections, contributing to efficient circuit design and enabling higher integration densities. FIG. 1C illustrates the semiconductor device with the backside vias 114A and 114B encapsulated by the ILD 132 and the STI 122 not in contact with the backside via 114A and 114B.

### Example Fabrication of Semiconductor Device with Front Via and Backside Power Delivery Network Structure

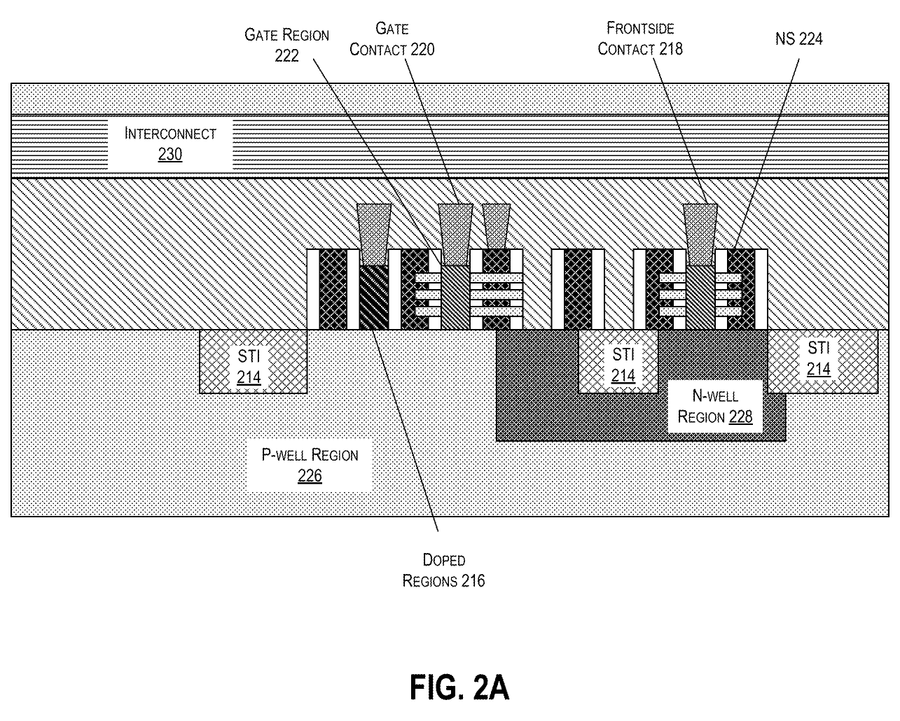

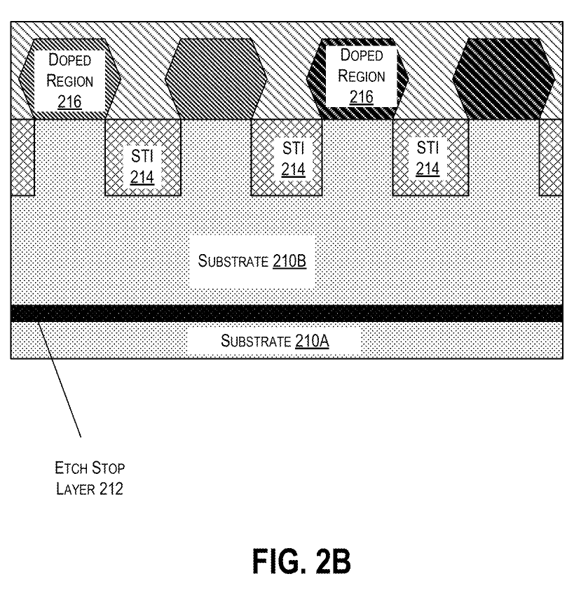

With the foregoing description of an example semiconductor device, it may be helpful to discuss an example process of manufacturing the same. To that end, FIGS. 2-8 illustrate various acts in the manufacture of a semiconductor device, consistent with illustrative embodiments. Figures denoted by A illustrate the LDMOS region and figures denoted by B illustrate the transistor region of the semiconductor device.

Reference now is made to FIGS. 2A-2B, which are simplified cross-section views of a semiconductor device, after the front end of line processes, consistent with an illustrative embodiment. The semiconductor device can include a first substrate 210A, a second substrate 210B, a SiGe layer 212, STI 214, doped regions 216, frontside contacts 218, gate contacts 220, gate regions 222, nanosheet gates, NS 224, a P-well region 226, an N-well region 228, a frontside interconnect 230.

In the illustrative example depicted in FIGS. 2A-2B, the semiconductor device is depicted as being on silicon as the first substrate 210A and the second substrate 210B, while it will be understood that other types as the first substrate 210A and the second substrate 210B, may be used as well, including, without limitation, monocrystalline Si, silicon germanium (SiGe), III-V compound semiconductor, II-VI compound semiconductor, or semiconductor-on-insulator (SOI). Group III-V compound semiconductors, for example, include materials having at least one group III element and at least one group V element, such as one or more of aluminum gallium arsenide (AlGaAs), aluminum gallium nitride (AlGaN), aluminum arsenide (AlAs), aluminum indium arsenide (AlIAs), aluminum nitride (AlN), gallium antimonide (GaSb), gallium aluminum antimonide (GaAlSb), gallium arsenide (GaAs), gallium arsenide antimonide (GaAsSb), gallium nitride (GaN), indium antimonide (InSb), indium arsenide (InAs), indium gallium arsenide (InGaAs), indium gallium arsenide phosphide (InGaAsP), indium gallium nitride (InGaN), indium nitride (InN), indium phosphide (InP) and alloy combinations including at least one of the foregoing materials. The alloy combinations can include binary (two elements, e.g., gallium (III) arsenide (GaAs)), ternary (three elements, e.g., InGaAs), and quaternary (four elements, e.g., aluminum gallium indium phosphide (AlInGaP)) alloys.

In various embodiments, the first substrate 210A and the second substrate 210B,can include any suitable material or combination of materials, such as doped or undoped silicon, glass, dielectrics, etc. For example, the substrate may include a silicon-on-insulator (SOI) structure, e.g., with a buried insulator layer, or a bulk material substrate, e.g., with appropriately doped regions, typically referred to as wells. In another embodiment , the substrate may be silicon with silicon oxide, nitride, or any other insulating film on top.

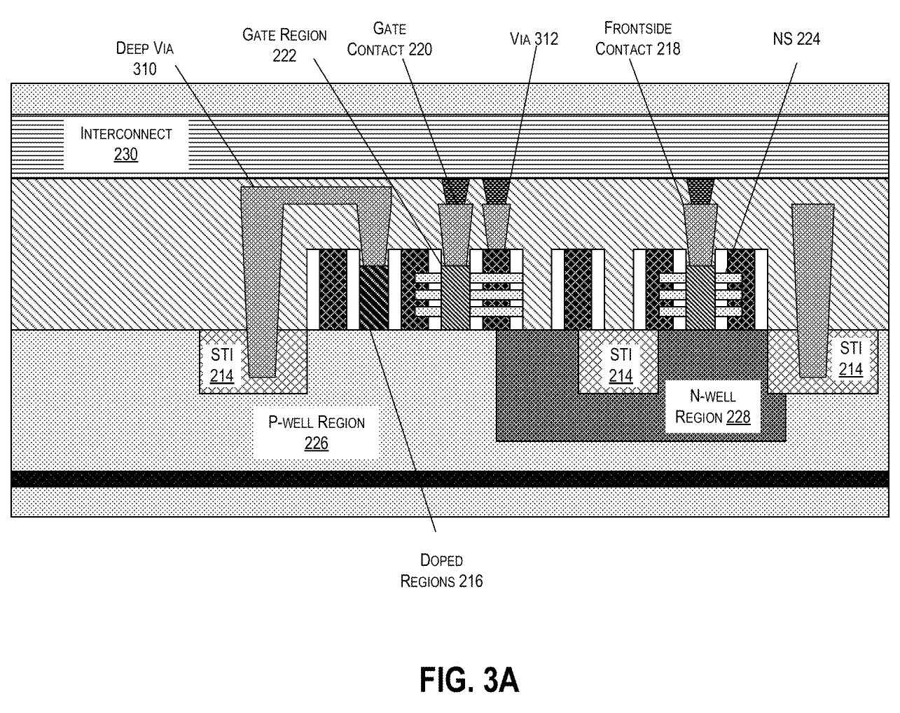

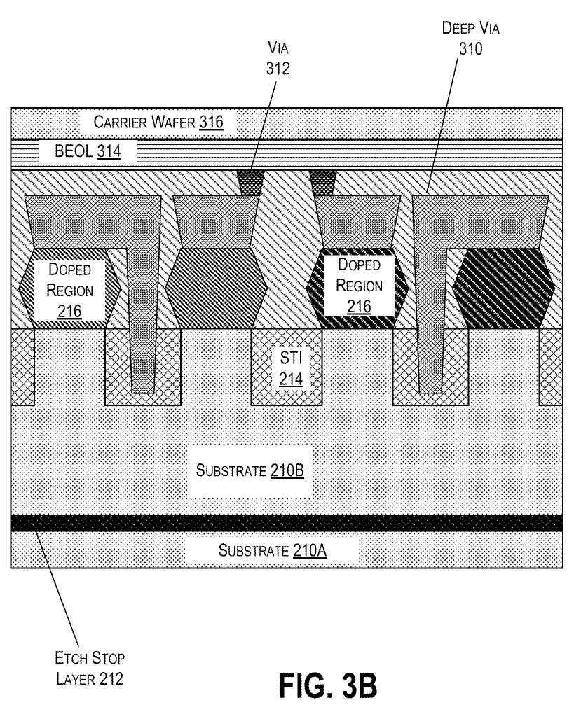

FIGS. 3A-3B illustrate a semiconductor device after the middle of line and back end of line processes, in accordance with some embodiments. In some embodiments, the deep vias 310 and vias 312 are formed. In some embodiments, a back end of line, BEOL 314 , is formed in the transistor region, which can include interconnects and wires to connect the semiconductor device to other chips. In some embodiments, carrier wafer bonding, also known as wafer-to-wafer bonding or chip-to-wafer bonding, is performed to join two semiconductor devices via a carrier wafer 316 together by creating a permanent bond between them. In some embodiments, the two semiconductor devices can be brought into contact and bonded at the atomic or molecular level, to create an interface. In an embodiment, the two semiconductor devices are brought into contact under controlled conditions, such as controlled pressure and temperature, to enable atomic or molecular bonding at the interface. Such bonding can be done at room temperature or with elevated temperatures. Alternatively, in some embodiments, an electric field and elevated temperature are utilized to create a bond. One semiconductor device can be made of semiconductor material, while the other can be a glass or silicon dioxide (SiO2) wafer. The electric field can cause ions in the glass or SiO2 to migrate and chemically bond with the semiconductor material in the other semiconductor device. In additional embodiments, a thin metal layer or metal alloy can be used as an intermediate bonding layer between the semiconductor devices.

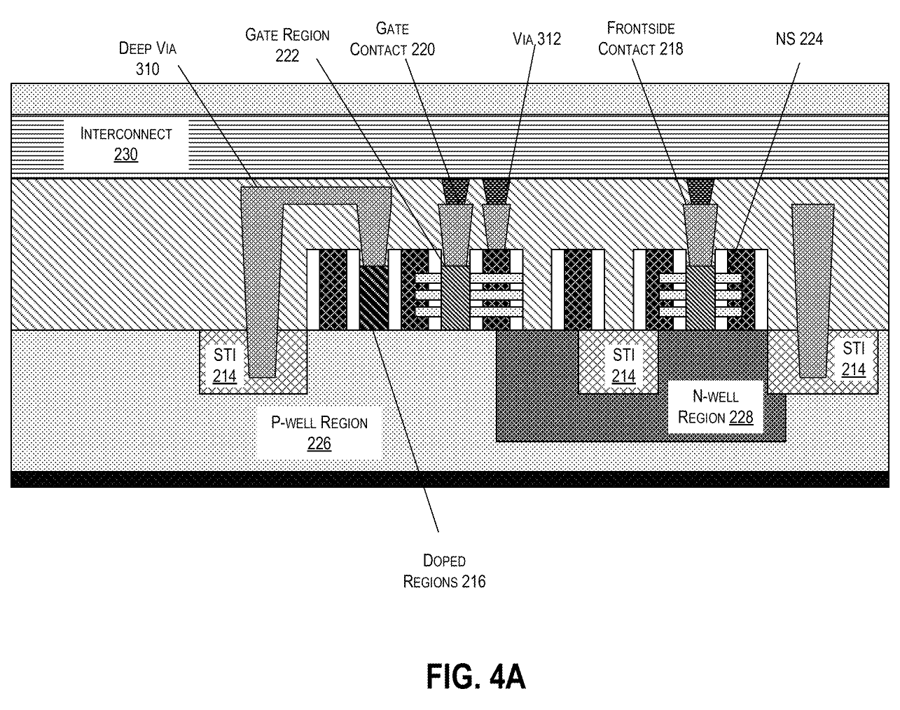

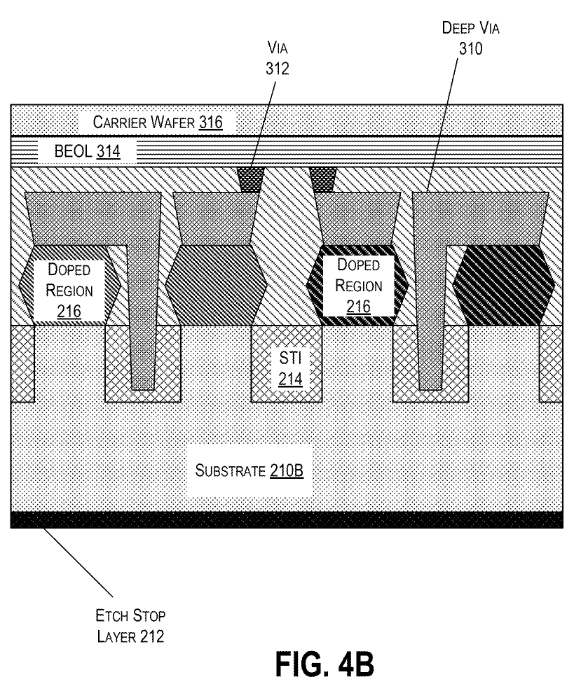

FIGS. 4A-4B illustrate a semiconductor device after removal of the first substrate, in accordance with some embodiments. In some embodiments, the first substrate is removed and the etch stop layer, e.g., the SiGe layer 212 is exposed. The wafer can be flipped, but for the sake of simplicity, it is not shown in the figures.

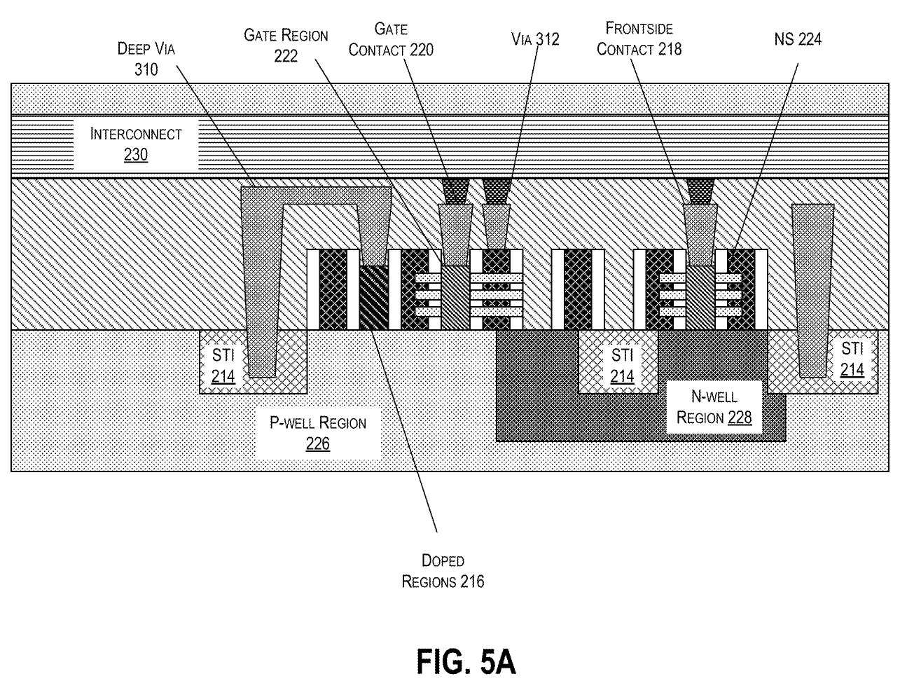

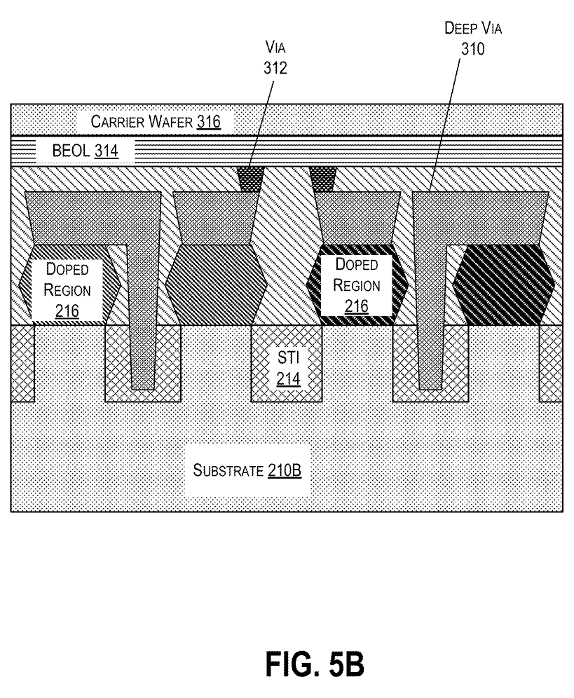

FIGS. 5A-5B illustrate a semiconductor device after the removal of the etch stop layer, in accordance with some embodiments. In some embodiments, the etch stop layer is removed.

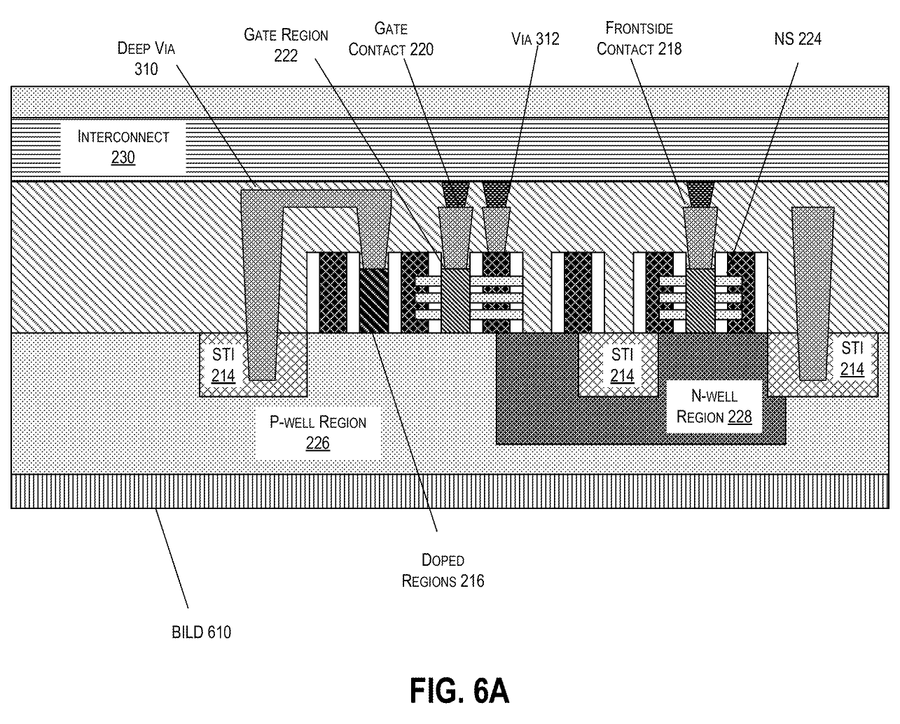

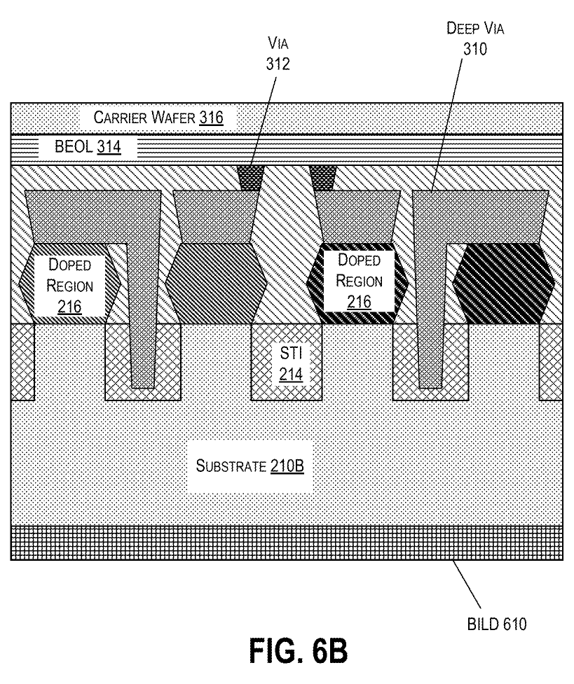

FIGS. 6A-6B illustrate a semiconductor device after the formation of backside interlayer dielectric, in accordance with some embodiments. In some embodiments, the BILD 610 is formed over the backside of the semiconductor device.

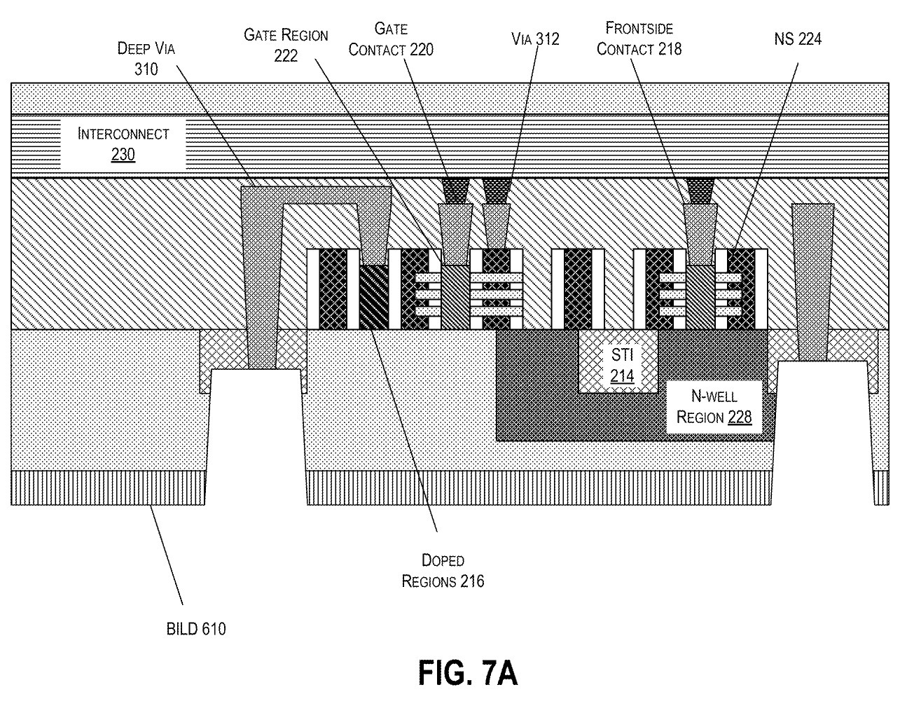

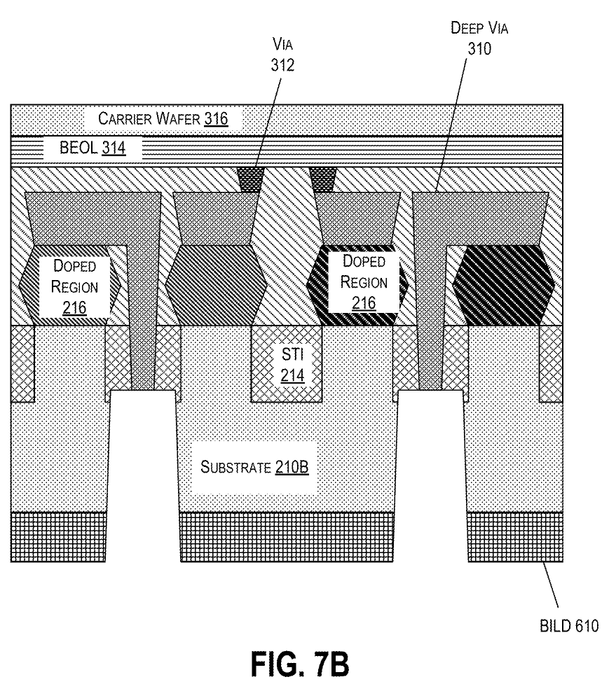

FIGS. 7A-7B illustrate a semiconductor device after the patterning of the backside metal interconnect, in accordance with some embodiments. In some embodiments, the backside of the semiconductor device is patterned by removing portions of the BILD 610 and the second substrate 210B to expose the bottom of the STI 214 and the deep via 310 .

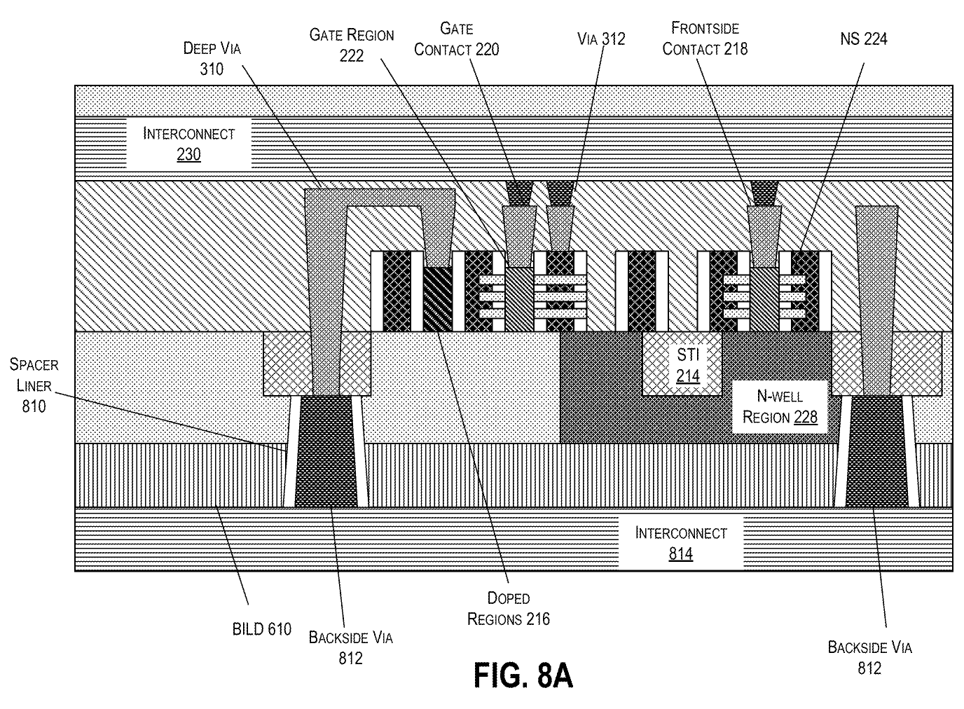

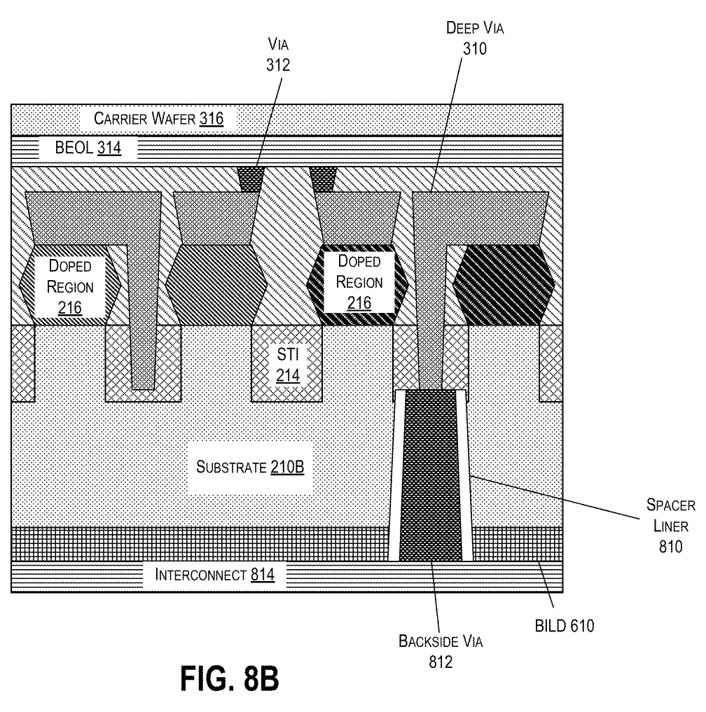

FIGS. 8A-8B illustrate a semiconductor device after the spacer formation, in accordance with some embodiments. In some embodiments, the spacer liner 810 is formed over the sidewalls of the patterned portions of the semiconductor device. The backside vias 812 are formed by filling the patterned portions of the semiconductor device. The backside metal interconnect 814 is formed over the backside of the semiconductor device.

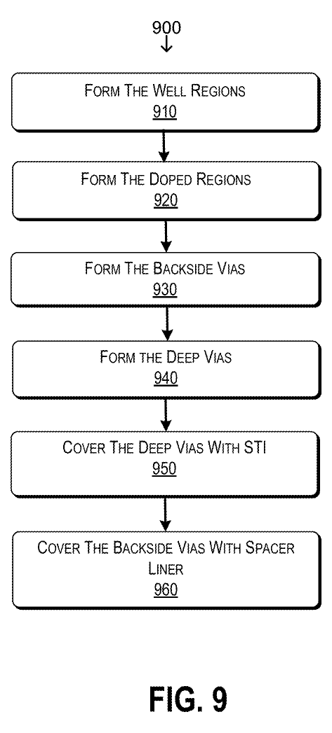

FIG. 9 illustrates a method 900 for forming the semiconductor device, in accordance with some embodiments. As shown by block 910 , the first well regions and the second well region are formed.

As shown by block 920 , the plurality of doped regions over the first well region and the second well region are formed.

As shown by block 930 , the first backside via and the second backside via are formed.

As shown by block 940 , the first deep via and the second deep via are formed.

As shown by block 950 , the first deep via and the second deep via are covered shallow trench isolation (STI).

As shown by block 960 , the first backside via and the second backside via are covered by a spacer liner.

In one aspect, the method and structures described above may be used in the fabrication of integrated circuit chips. The resulting integrated circuit chips can be distributed by the fabricator in raw wafer form (that is, as a single wafer that has multiple unpackaged chips), as a bare die, or in a packaged form. In the latter case, the chip may be mounted in a single chip package (such as a plastic carrier, with leads that are affixed to a motherboard or other higher-level carrier) or in a multichip package (such as a ceramic carrier that has either or both surface interconnections or buried interconnections). In any case, the chip can then be integrated with other chips, discrete circuit elements, and/or other signal processing devices as part of either (a) an intermediate product, such as a motherboard, or (b) an end product. The end product can be any product that includes integrated circuit chips, ranging from low-end applications, such as toys, to advanced computer products having a display, a keyboard or other input device, and a central processor.

### Conclusion

The descriptions of the various embodiments of the present teachings have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to explain the principles of the embodiments, the practical application or technical improvement over technologies found in the marketplace, or to enable others of ordinary skill in the art to understand the embodiments disclosed herein.

While the foregoing has described what are considered to be the best state and/or other examples, it is understood that various modifications may be made therein and that the subject matter disclosed herein may be implemented in various forms and examples, and that the teachings may be applied in numerous applications, only some of which have been described herein. It is intended by the following claims to claim any and all applications, modifications, and variations that fall within the true scope of the present teachings.

The components, steps, features, objects, benefits, and advantages that have been discussed herein are merely illustrative. None of them, nor the discussions relating to them, are intended to limit the scope of protection. While various advantages have been discussed herein, it will be understood that not all embodiments necessarily include all advantages. Unless otherwise stated, all measurements, values, ratings, positions, magnitudes, sizes, and other specifications that are set forth in this specification, including in the claims that follow, are approximate, not exact. They are intended to have a reasonable range that is consistent with the functions to which they relate and with what is customary in the art to which they pertain.

Numerous other embodiments are also contemplated. These include embodiments that have fewer, additional, and/or different components, steps, features, objects, benefits and advantages. These also include embodiments in which the components and/or steps are arranged and/or ordered differently.

While the foregoing has been described in conjunction with exemplary embodiments, it is understood that the term “exemplary” is merely meant as an example, rather than the best or optimal. Except as stated immediately above, nothing that has been stated or illustrated is intended or should be interpreted to cause a dedication of any component, step, feature, object, benefit, advantage, or equivalent to the public, regardless of whether it is or is not recited in the claims.

It will be understood that the terms and expressions used herein have the ordinary meaning as is accorded to such terms and expressions with respect to their corresponding respective areas of inquiry and study except where specific meanings have otherwise been set forth herein. Relational terms such as first and second and the like may be used solely to distinguish one entity or action from another without necessarily requiring or implying any actual relationship or order between such entities or actions. The terms “comprises,” “comprising,” or any other variation thereof, are intended to cover a non-exclusive inclusion, such that a process, method, article, or apparatus that comprises a list of elements does not include only those elements but may include other elements not expressly listed or inherent to such process, method, article, or apparatus. An element proceeded by “a” or “an” does not, without further constraints, preclude the existence of additional identical elements in the process, method, article, or apparatus that comprises the element.

The Abstract of the Disclosure is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments have more features than are expressly recited in each claim. Rather, as the following claims reflect, the inventive subject matter lies in less than all features of a single disclosed embodiment. Thus, the following claims are hereby incorporated into the Detailed Description, with each claim standing on its own as a separately claimed subject matter.

What is claimed is:

1. A semiconductor device, comprising:
a first well region;
a second well region adjacent to the first well region;
one or more doped regions over each of the first well region and the second well region;
a first backside via on a first side of the semiconductor device;
a second backside via on a second side of the semiconductor device, wherein the first side is located on an opposite side of the second side;
a first deep via connecting the first backside via to a frontside contact;
a second deep via over the second backside via; and
shallow trench isolation (STI) covering the first deep via and the second deep via,
wherein the first backside via and the second backside via are covered by a spacer liner.

2. The semiconductor device of claim 1, further comprising:
a plurality of source/drain regions, wherein each of the plurality of source/drain regions are bounded by a first gate region.

3. The semiconductor device of claim 1, further comprising:
a portion of the STI within the second well region beneath a source region and a drain region.

4. The semiconductor device of claim 1, further comprising:
one or more gate regions extending over the first well region and the second well region, and
a second gate region with no doped region adjacent to it on a drain side.

5. The semiconductor device of claim 1, wherein the semiconductor device is isolated laterally by a through-via interconnect.

6. The semiconductor device of claim 1, wherein the semiconductor device is isolated vertically by a low-k interlayer dielectric (ILD).

7. The semiconductor device of claim 1, further comprising:
horizontally oriented nanosheet gates, wherein the horizontally oriented nanosheet gates include silicon.

8. The semiconductor device of claim 1, further comprising a gate contact over at least one gate.

9. A method for fabrication of a semiconductor device, the method comprising:
forming a first well region;
forming a second well region adjacent to the first well region;
forming one or more doped regions over each of the first well region and the second well region;
forming a first backside via on a first end of the semiconductor device;
forming a second backside via on a second end of the semiconductor device;
forming a first deep via connecting the first backside via to a frontside contact;
forming a second deep via over the second backside via;
covering the first deep via and the second deep via by shallow trench isolation (STI); and
covering the first backside via and the second backside via by a spacer liner.

10. The method of claim 9, further comprising:
forming a plurality of source/drain regions; and
bounding each of the plurality of source/drain regions by a gate region.

11. The method of claim 9, further comprising forming a portion of the STI within the second well region beneath a source region and a drain region.

12. The method of claim 9, further comprising extending a gate region over the first well region and the second well region, wherein the gate region has no doped region adjacent to it on a drain side.

13. The method of claim 9, further comprising laterally isolating the semiconductor device by a through-via interconnect.

14. The method of claim 9, further comprising vertically isolating the semiconductor device by a low-k interlayer dielectric (ILD).

15. The method of claim 9, further comprising forming horizontally oriented nanosheet gates, wherein the horizontally oriented nanosheet gates include silicon.

16. The method of claim 9, further comprising forming a gate contact over a gate region.

17. A semiconductor device, comprising:
a well region;
a plurality of doped regions over the well region;
a backside via on a first end of the semiconductor device;
a deep via connecting the backside via to a frontside contact; and
shallow trench isolation (STI) covering the deep via,
wherein:
a gate region extends over the well region, and
the gate region has no doped region adjacent to it on a drain side.

18. The semiconductor device of claim 17, wherein the backside via is covered by a spacer liner.

19. The semiconductor device of claim 17, further comprising a plurality of source/drain regions, wherein each of the plurality of source/drain regions are bounded by a gate region.

20. The semiconductor device of claim 17, further comprising:
horizontally oriented nanosheet gates, wherein the horizontally oriented nanosheet gates include silicon; and
a gate contact over the gate region.
